(19) United States
(12) Patent Application Publication
(10) Pub. No.: US 2015/0155025 A1
(43) Pub. Date: Jun. 4, 2015

(54) SEMICONDUCTOR MEMORY DEVICE, REFRESH CONTROL SYSTEM, AND REFRESH CONTROL METHOD

(71) Applicant: SK hynix Inc., Gyeonggi-do (KR)

(72) Inventors: Jae-Seung LEE, Gyeonggi-do (KR); Choung-Ki SONG, Gyeonggi-do (KR)

(21) Appl. No.: 14/297,336

(22) Filed: Jun. 5, 2014

(30) Foreign Application Priority Data
Dec. 4, 2013 (KR) 10-2013-0149923

(51) Int. Cl. G11C 11/406

(52) U.S. Cl. CPC G11C 11/406

(57) ABSTRACT

A semiconductor memory device includes a normal command generation unit suitable for generating a normal refresh command in response to a refresh command; a smart command generation unit suitable for performing a counting operation on the refresh command to generate a plurality of smart refresh commands which are activated at a predetermined period; and a refresh operation unit suitable for performing a refresh operation in response to the normal refresh command and the plurality of smart refresh commands, wherein the smart command generation unit resets the counting operation when entering into the refresh operation.

### CROSS-REFERENCE TO RELATED APPLICATIONS

The present application claims priority of Korean Patent Application No. 10-2013-0149923, filed on Dec. 4, 2013, which is incorporated herein by reference in its entirety.

### BACKGROUND

1. Field

Exemplary embodiments of the present invention relate to a semiconductor design technology, and more particularly, to a semiconductor memory device for performing a refresh operation, a refresh control system, and a refresh control method.

2. Description of the Related Art

In general, a semiconductor memory device such as a double data rate synchronous dynamic random access memory (DDR SDRAM) includes a plurality of memory banks for storing data, and each of the plurality of memory banks includes a plurality of memory cells in the tens of millions. Each memory cell is composed of a cell capacitor and a cell transistor and the semiconductor memory device stores data by charging or discharging electrical charge in the cell capacitor.

It would be ideal if the electrical charge stored in the cell capacitor stayed constant on its own. However, the amount of electrical charge stored in the cell capacitor varies due to a voltage difference between the cell capacitor and peripheral circuits. That is, electrical charge may flow out of the cell capacitor when it is in the charged state, or flow in the cell capacitor when the cell capacitor has been discharged. As the amount of electrical charge in the cell capacitor varies, the state of data stored in the cell capacitor varies. This causes loss of the stored data. Accordingly, the semiconductor memory device performs a refresh operation in order to prevent the loss of the stored data. Since the refresh operation is well known in the art, a detailed description will be omitted.

Meanwhile, the degree of integration of the semiconductor memory device has been increased as the process technology has been developed. The increase in degree of integration of the semiconductor memory device influences the size of the memory bank. A decrease in the size of the memory bank means that a gap between the memory cells becomes reduced and the distance between word lines coupled to adjacent memory cells becomes closer.

Generally, there is no concern with respect to the distance between the word lines. However, new issues have arisen as the distance between the word lines has decreased. Among the new issues is a coupling effect that occurs between word lines.

In a semiconductor memory device, an active operation on a word line is required in order to access any memory cell coupled to the word line. As the distance between the word lines becomes decreased, such an active operation causes the coupling effect to adjacent word lines. When the coupling effect occurs in the adjacent word lines, memory cells coupled to the adjacent word lines have difficulty maintaining stored data. This may increase the probability data loss.

To alleviate the above concern, the semiconductor memory device performs a refresh operation on all of memory cells in a memory bank. That is, the refresh operation may be frequently performed so as to prevent the loss of data. However, since an increase in the number of times that the refresh operation is performed deteriorates the operating efficiency of the semiconductor memory device, there are limitations on the number of times a refresh operation may be performed.

### SUMMARY

Various exemplary embodiments of the present invention are directed to a semiconductor memory device capable of smartly controlling a refresh operation to alleviate concerns occurring due to a high degree of integration.

In accordance with an exemplary embodiment of the present invention, a semiconductor memory device may include a normal command generation unit suitable for generating a normal refresh command in response to a refresh command, a smart command generation unit suitable for performing a counting operation on the refresh command to generate a plurality of smart refresh commands which are activated at a predetermined period, and a refresh operation unit suitable for performing a refresh operation in response to the normal refresh command and the plurality of smart refresh commands, wherein the smart command generation unit resets the counting operation when entering into the refresh operation.

The plurality of smart refresh commands may be activated in a given sequence at each predetermined period.

In accordance with another exemplary embodiment of the present invention, a semiconductor memory system may include: a normal command generation unit suitable for generating a normal refresh command during a refresh operation; a smart command generation unit suitable for generating a plurality of smart refresh commands during the refresh operation, and outputting the plurality of smart refresh commands in response to a preset priority; and a refresh operation unit suitable for performing the refresh operation in response to the normal refresh command and the plurality of smart refresh commands.

The plurality of smart refresh commands may be activated to correspond to at least one word line among the plurality of word lines.

In accordance with still another exemplary embodiment of the present invention, a refresh control system may include a semiconductor memory device having a plurality of word lines which are grouped based on group information during a smart refresh operation, and a memory controller suitable for changing a period of the a refresh operation of the semiconductor memory device in response to the group information on the plurality of word lines, wherein the semiconductor memory device performs the smart refresh operation based on the refresh operation.

The plurality of word lines may be activated in response to priority information during the smart refresh operation.

In accordance with still another exemplary embodiment of the present invention, a refresh control method may include performing a normal refresh operation on a plurality of word lines in response to a refresh command, performing a first smart refresh operation on a first word line group having a first type priority in response to the refresh command, and performing a second smart refresh operation on a second word line group having a second type priority in response to the refresh command.

In performing the first smart refresh operation, first word lines included in the first word line group may be sequentially activated in response to the first type priority. In performing the second smart refresh operation, second word lines included in the second word line group may be sequentially activated in response to the second type priority.

In accordance with still another exemplary embodiment of the present invention, a semiconductor memory system may include a normal command generation unit suitable for generating a normal refresh command in response to a refresh command, a smart command generation unit suitable for generating a plurality of smart refresh commands every predetermined period by counting the refresh commands, wherein the plurality of smart refresh commands are generated in a sequence set based on a priority, and a refresh operation unit suitable for performing a refresh operation in response to the normal refresh command and the plurality of smart refresh commands.

According to the embodiments of the present invention, refresh operation efficiency may be maximized by smartly controlling the refresh operation, so that loss of data may be prevented without deteriorating operating efficiency of the semiconductor memory device.

### BRIEF DESCRIPTION OF THE DRAWINGS

FIG. 1 is a block diagram illustrating a semiconductor memory device in accordance with an exemplary embodiment of the present invention.

FIGS. 2 and 3 are waveforms explaining operations of the semiconductor memory device shown in FIG. 1.

FIG. 4 is a detailed block diagram illustrating a smart command generation unit shown in FIG. 1.

FIG. 5 is a block diagram illustrating a semiconductor memory device in accordance with another exemplary embodiment of the present invention.

FIG. 6 is a block diagram describing a plurality of word lines.

FIGS. 7A to 7D are waveforms explaining operations of the semiconductor memory device shown in FIG. 5.

FIG. 8 is a block diagram illustrating a refresh control system in accordance with another exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. The drawings are not necessarily to scale and in some instances, proportions may have been exaggerated in order to clearly illustrate features of the embodiments. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

Refresh operations performed in the exemplary embodiments of the present invention are classified into two types. A first type is a normal refresh operation that is performed in response to a normal refresh command such as a self refresh command or an auto refresh command. The second type is a smart refresh operation which is performed on a given word line.

The smart refresh operation will now be described. A word line is activated or deactivated by an active operation. However, due to an increase in the degree of integration, a disturbance occurs in a word line adjacent to the word line where the active operation is being performed. When this happens, the voltage of the adjacent word line becomes unstable. Accordingly, data stored in memory cells coupled to the adjacent word line may be lost. To alleviate this concern, a refresh operation according to the exemplary embodiments of the present invention is performed on the adjacent word line. As a result, loss of the data may be prevented. Such a refresh operation is defined as a smart refresh operation.

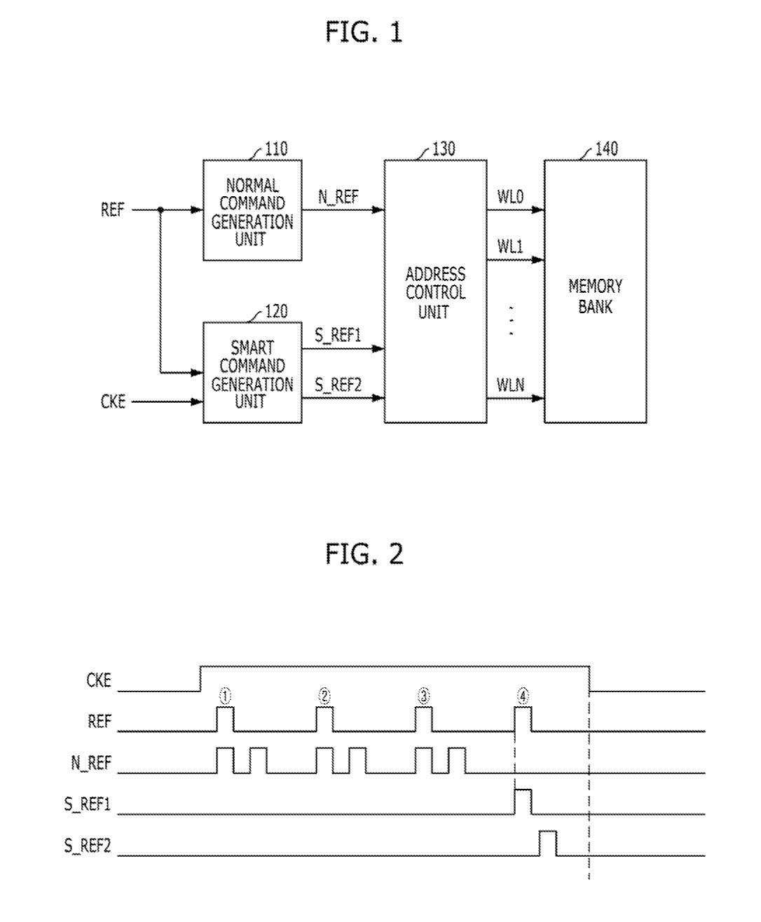

FIG. 1 is a block diagram illustrating a semiconductor memory device in accordance with an exemplary embodiment of the present invention.

Referring to FIG. 1, the semiconductor memory device includes a normal command generation unit 110, a smart command generation unit 120, an address control unit 130, and a memory bank 140.

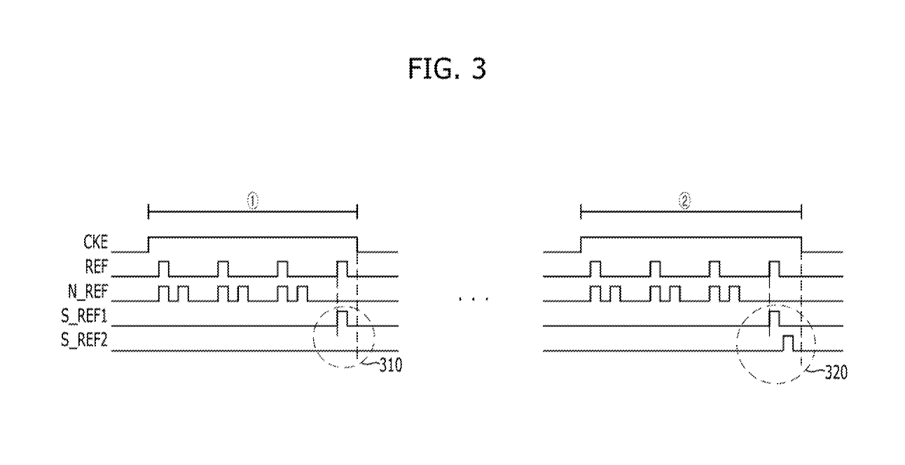

The normal command generation unit 110 generates a normal refresh command N_REF in response to a refresh command REF. The refresh command REF is activated during a refresh operation. The smart command generation unit 120 generates first and second smart refresh commands S_REF1 and S_REF2, which are activated on a predetermined cycle, by counting the refresh command REF. The smart command generation unit 120 sequentially generates the first and second smart refresh commands S_REF1 and S_REF2 in response to the refresh command REF and a clock enable signal CKE. Here, the clock enable signal CKE is a signal for controlling whether to toggle a clock signal used in the semiconductor memory device. The clock enable signal CKE is inactivated before the refresh operation and may obtain information on whether or not to enter into the refresh operation based on the clock enable signal CKE. A detailed description of the normal refresh command N_REF and the first and second smart refresh commands S_REF1 and S_REF2 will be provided with reference to FIGS. 2 and 3.

The address control unit 130 controls a plurality of word lines WL0, WL1, . . . , WLN (N being a nature number) to be activated in response to the normal refresh command N_REF and the first and second smart refresh commands S_REF1 and S_REF2. The address control unit 130 may be provided with a generating circuit for generating an address corresponding to the plurality of word lines WL0, WL1, . . . , WLN, a decoding circuit for decoding the address, a driving circuit for driving the plurality of word lines WL0, WL1, . . . , WLN in response to a decoded signal, and the like. The memory bank 140 includes a plurality of memory cells for storing data, each coupled to a corresponding one of the word lines WL0, WL1, . . . , WLN. Among the word lines WL0, WL1, . . . , WLN, a refresh operation is performed on an activated word line. The above described address control unit 130 and memory bank 140 may be classified into a refresh operation unit for performing a refresh operation in response to the normal refresh command N_REF and the first and second smart refresh commands S_REF1 and S_REF2.

FIGS. 2 and 3 are waveforms explaining operations of the semiconductor memory device shown in FIG. 1.

In a simplified example, the smart refresh operation is performed once after a normal refresh operation is performed three times. The information on entry/exit into/from the refresh operation is obtained based on the clock enable signal CKE. The entry into the refresh operation is made when the clock enable signal CKE transits to a logic high level from a logic low level, and the exit from the refresh operation is made when the clock enable signal CKE transits to a logic low level from a logic high level.

FIG. 2 shows a case of an exit from after a normal refresh operation and a smart refresh operation. As shown in FIG. 2, the refresh command REF is activated every predetermined period after the clock enable signal CKE transits to a logic high level from a logic low level, that is, after entry into the refresh operation. Further, the refresh command REF is not activated after the clock enable signal CKE transits to a logic low level from a logic high level, that is, after the exit from the refresh operation. The normal refresh command N_REF and the first and second smart refresh commands S_REF1 and S_REF2 are activated in response to the refresh command REF.

Referring to FIG. 2, the normal refresh command N_REF corresponding to the normal refresh operation is activated in response to the refresh command REF (see \textcircled{1}, \textcircled{2}, \textcircled{3}). A case where the normal refresh command N_REF is activated twice in response to one refresh command REF will now be explained as an example. The first and second smart refresh commands S_REF1 and S_REF2 corresponding to the smart refresh operation are activated in response to the refresh command REF (see \textcircled{4}). Now, a case where the first and second smart refresh commands S_REF1 and S_REF2 are sequentially activated in response to one refresh command REF is explained as an example.

For reference, the smart refresh operation is performed in response to the first and second smart refresh commands S_REF1 and S_REF2. The first and second smart refresh commands S_REF1 and S_REF2 correspond to word lines adjacent to a frequently activated word line. In other words, when the frequently activated word line corresponds to an Nth address, the first smart refresh command S_REF1 corresponds to a word line of an (N+1)th address and the second smart refresh command S_REF2 corresponds to a word line of an (N−1)th address.

FIG. 3 shows a case of an exit from a refresh operation in a state where the smart refresh operation is not finished. In a simplified description, the refresh operation is divided into a first refresh operation section (\textcircled{1}) where the exit from the refresh operation is performed in a state that the smart refresh operation has not been finished (‘310’), and a second refresh operation section (\textcircled{2}) where the exit from the refresh operation is performed in a state that the smart refresh operation has been completely finished (‘320’). As shown in FIG. 3, the exit from the refresh operation exists between the first refresh operation section (\textcircled{1}) and the second refresh operation section (\textcircled{2}).

Referring to FIG. 3, during the smart refresh operation in the first refresh operation section (\textcircled{1}) and the second refresh operation section (\textcircled{2}), the first smart refresh command S_REF1 is activated prior to the second smart refresh command S_REF2. Hereinafter, a case where the first smart refresh command S_REF1 is activated prior to the second smart refresh command S_REF2 is explained in detail.

Referring back to FIG. 1, the smart command generation unit 120 resets the first and second smart refresh commands S_REF1 and S_REF2 in response to the clock enable signal CKE. That is, the smart command generation unit 120 counts the refresh command REF and sequentially activates the first and second smart refresh commands S_REF1 and S_REF2 every predetermined period. At this time, the smart command generation unit 120 resets a counting operation on the refresh command REF in response to the clock enable signal CKE corresponding to the refresh operation. Accordingly, the smart command generation unit 120 may generate the first smart refresh command S_REF1, which is activated prior to the second smart refresh command S_REF2, during the smart refresh operation.

As described above, the semiconductor memory device in accordance with the exemplary embodiment of the present invention may control the first smart refresh command S_REF1 to be activated prior to the second smart refresh command S_REF2 by resetting the counting operation on the refresh command REF during the refresh operation.

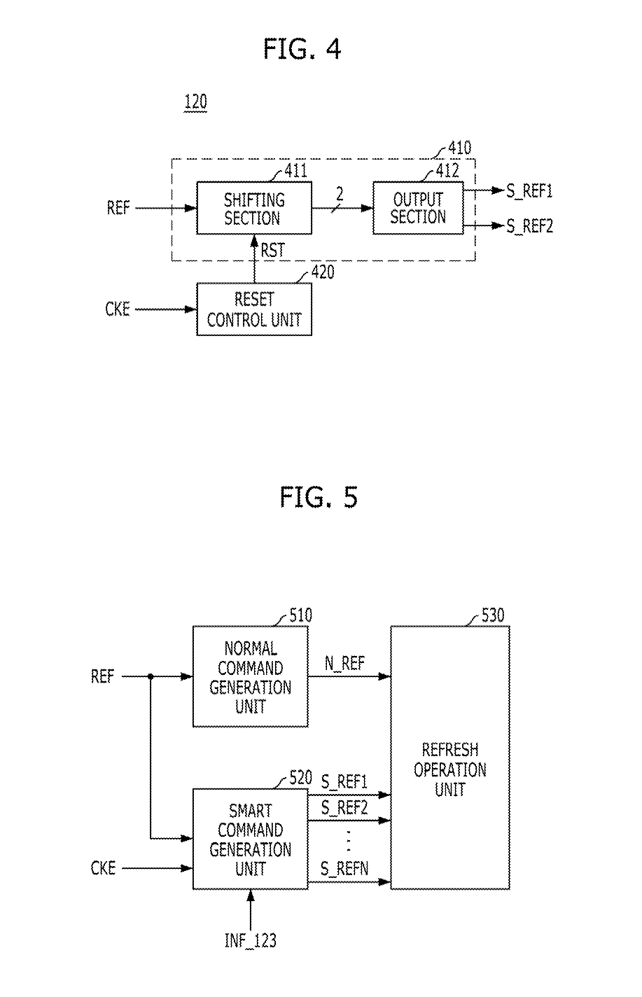

FIG. 4 is a detailed block diagram illustrating the smart command generation unit 120 shown in FIG. 1.

Referring to FIG. 4, the smart command generation unit 120 includes a command counting unit 410 and a reset control unit 420.

The command counting unit 410 counts the refresh command REF and generates the first and second smart refresh commands S_REF1 and S_REF2 every predetermined period. The command counting unit 410 includes a shifting section 411 and an output section 412. The shifting section 411 performs a shifting operation whenever the refresh command REF is activated and may be composed of a plurality of flip-flops whose number corresponds to the predetermined period. The output section 412 receives an output signal of the shifting section 411 and controls a pulse of the output signal to output the first and second smart refresh commands S_REF1 and S_REF2.

The reset control unit 420 generates a reset signal RST in response to the clock enable signal CKE. The reset signal RST is used to reset a counting operation of the command counting unit 410. In detail, the reset signal RST is inputted to the shifting section 411 of the command counting unit 410, and the shifting section 411 resets stored data in response to the reset signal RST. As a result, since the reset signal RST is activated at the entry into the refresh operation and the counting operation of the command counting unit 410 is reset in response to the reset signal RST, the smart command generation unit 120 may generate the first smart refresh command S_REF1 to be activated prior to the second smart refresh command S_REF2 during the smart refresh operation.

FIG. 5 is a block diagram illustrating a semiconductor memory device in accordance with another exemplary embodiment of the present invention.

Referring to FIG. 5, the semiconductor memory device includes a normal command generation unit 510, a smart command generation unit 520, and a refresh operation unit 530.

The normal command generation unit 510 generates a normal refresh command N_REF in response to a refresh command REF during a refresh operation. The smart command generation unit 520 generates a plurality of smart refresh commands S_REF1, S_REF2, . . . , S_REFN (N being a nature number) during the refresh operation and determines an output sequence of the plurality of smart refresh commands S_REF1, S_REF2, . . . , S_REFN in response to priority information INF_123. The refresh operation unit 530 performs the refresh operation in response to the normal refresh command N_REF and the plurality of smart refresh commands S_REF1, S_REF2, . . . , S_REFN.

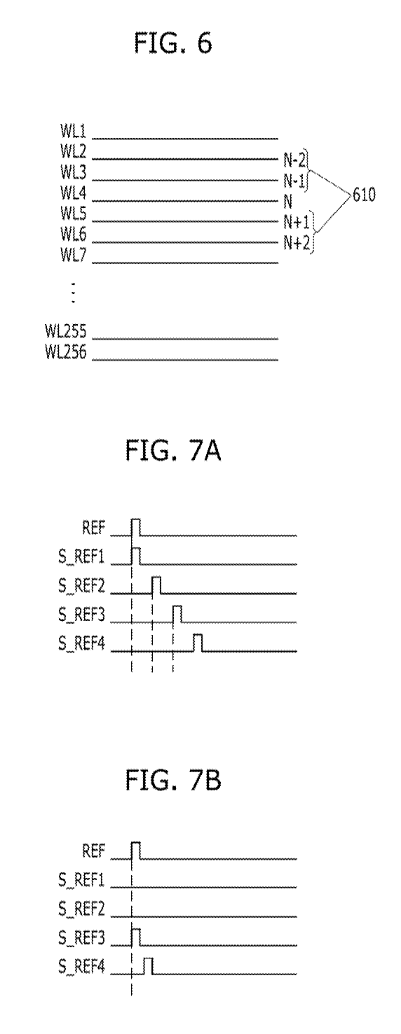

Prior to an explanation of the operation of the semiconductor memory device shown in FIG. 5, a plurality of word lines of the semiconductor memory device in accordance with this exemplary embodiment of the present invention will be explained with reference to FIG. 6. Though it is not shown in FIG. 5, the refresh operation unit 530 may include the memory bank 140 of FIG. 1, which includes a plurality of word lines.

FIG. 6 is a block diagram describing the plurality of word lines. For a simplified description, a case where the memory bank 140 includes 256 word lines will be explained.

Referring to FIG. 6, first to 256th word lines WL1, WL2, . . . , WL256 are shown. During a normal refresh operation the first to 256th word lines WL1, WL2, . . . , WL256 are sequentially activated from the first word line WL1 to the 256th word line WL256. The semiconductor memory device in accordance with an exemplary embodiment of the present invention performs a smart refresh operation by grouping the word lines into a given number. When a frequently activated word line is the fourth word line WL4, the smart refresh operation is performed on a word line group 610 adjacent to the frequently activated word line. The word line group 610 includes 4 word lines, e.g., the second word lines WL2, the third word lines WL3, the fifth word line WL5 and the sixth word line WL6, as one group.

Referring to FIGS. 5 and 6, when the frequently activated word line corresponds to an Nth address, the refresh operation unit 530 controls addresses corresponding to the word line group 610, i.e., (N−2)th address, (N−1)th address, (N+1)th address and (N+2)th address, to be activated during the smart refresh operation. The smart command generation unit 520 sequentially outputs first to fourth smart refresh commands S_REF1, S_REF2, S_REF3 and S_REF4 corresponding to the addresses of the word line group 610, i.e., (N−2)th address, (N−1)th address, (N+1)th address and (N+2)th address, in response to the priority information INF_123. For reference, the smart command generation unit 520 is reset before the smart refresh operation, and such a reset operation provides a condition that the smart command generation unit 520 stably generates the first to fourth smart refresh commands S_REF1, S_REF2, S_REF3 and S_REF4.

The semiconductor memory device in accordance with an exemplary embodiment of the present invention may output the smart refresh commands according to a preset priority during the smart refresh operation. This means that a word line to be activated during the smart refresh operation may be determined in response to a priority.

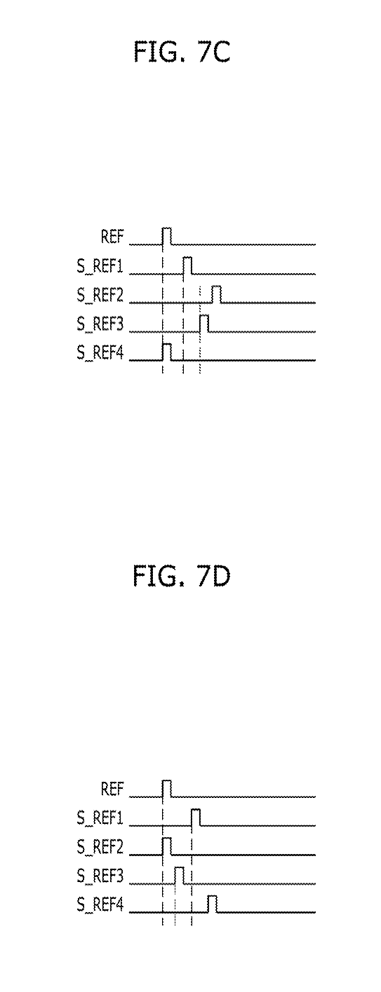

FIGS. 7A to 7D are waveforms explaining operations of the semiconductor memory device shown in FIG. 5. In a simplified description, a smart refresh operation is performed on 4 word lines which form one group. In FIGS. 7A to 7D, only a section where the smart refresh operation is performed is shown.

Referring to FIGS. 7A to 7D, though there are various cases where the first to fourth smart refresh commands S_REF1, S_REF2, S_REF3 and S_REF4 are outputted in response to the priority information INF_123, only 4 cases are explained as an example.

In FIG. 7A, priority is determined such that the first to fourth smart refresh commands S_REF1, S_REF2, S_REF3 and S_REF4 are sequentially activated from the first smart refresh command S_REF1 to the fourth smart refresh commands S_REF4 in response to the refresh command REF. In FIG. 7B, priority is given to word lines disposed below a frequently activated word line. The first smart refresh command S_REF1 and the second smart refresh command S_REF2 are not activated. In FIG. 7C, priority is given to word lines disposed away from frequently activated word lines. In FIG. 7D, priority is given to word lines disposed close to frequently activated word lines.

The semiconductor memory device in accordance with an exemplary embodiment of the present invention may control a smart refresh operation by grouping word lines into a given number and may determine a priority of the word lines to be activated in one word line group. While the exemplary embodiment of FIGS. 7A to 7D has been described with respect to 4 cases, there are various other ways where it may be possible for the first to fourth smart refresh commands S_REF1, S_REF2, S_REF3 and S_REF4 to be outputted.

The semiconductor memory device in accordance with an exemplary embodiment of the present invention may selectively use any case shown in FIGS. 7A to 7D (or others) during the refresh operation. For example, if the semiconductor memory device uses the priority shown in FIG. 7A during a first refresh operation, the semiconductor memory device may use any priority shown in FIGS. 7B to 7D other than FIG. 7A during a second refresh operation.

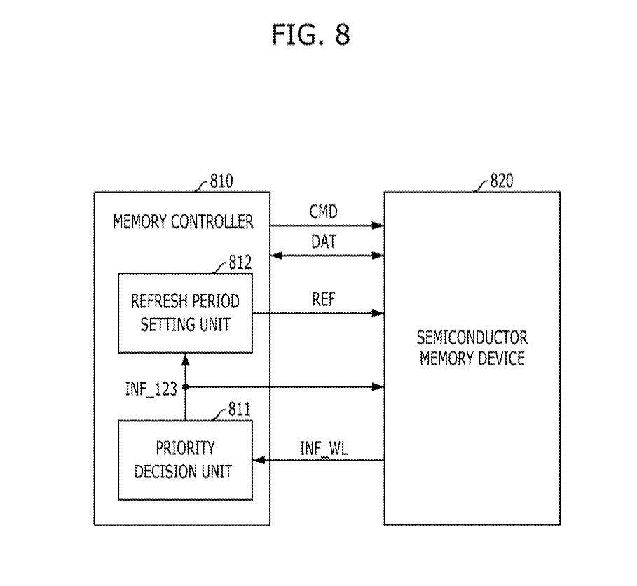

FIG. 8 is a block diagram illustrating a refresh control system in accordance with another exemplary embodiment of the present invention.

Referring to FIG. 8, the refresh control system includes a memory controller 810 and a semiconductor memory device 820.

The memory controller 810 generates a command CMD for controlling the semiconductor memory device 820, and provides the command CMD to the semiconductor memory device 820. The command CMD may include a write command for storing data DAT in the semiconductor memory device 820, a read command for reading out data DAT stored in the semiconductor memory device 820, and the like. Further, the command CMD may include a refresh command REF. For a simple description, the refresh command REF is explained separately from the command CMD.

The memory controller 810 includes a priority decision unit 811 and a refresh period setting unit 812.

The priority decision unit 811 receives word line group information INF_WL from the semiconductor memory device 820 and generates priority information INF_123. The word line group information INF_WL includes information on a plurality of word lines grouped during a smart refresh operation of the semiconductor memory device 820, e.g., the number of the word lines grouped during the smart refresh operation. That is to say the priority decision unit 811 may change the priority information INF_123 based on the number of the grouped word lines, e.g., 2 or 4. While the priority decision unit 811 in accordance with the exemplary embodiment of the present invention generates the priority information INF_123 in response to the word line group information INF_WL, the priority decision unit 811 may generate the priority information INF_123 in response to other information such as type of stored data, system speed, and the like.

The refresh period setting unit 812 sets an activation period of the refresh command REF in response to the priority information INF_123. For reference, the priority information INF_123 includes word line group information INF_WL and information on an activated word line of a word line group. Accordingly, the refresh period setting unit 812 may change the activation period of the refresh command REF depending on activated word line information.

The semiconductor memory device 820 performs a refresh operation in response to the refresh command REF provided from the memory controller 810. The semiconductor memory device 820 calculates the number of the grouped word lines during the smart refresh operation in consideration of an arrangement of word lines and a process characteristic, and provides the word line group information INF_WL corresponding to the calculated number of the grouped word lines to the memory controller 810. The semiconductor memory device 820 performs a normal refresh operation in response to the refresh command REF provided from the memory controller 810 and performs the smart refresh operation in response to the refresh command REF and the priority information INF_123.

As described above, the refresh control system in accordance with the exemplary embodiment of the present invention may determine a priority/sequence of a word line to be activated during the smart refresh operation and may control a period of a refresh operation in response to the word line group information INF_WL of the semiconductor memory device 820.

According to the exemplary embodiments of the present invention as described above, the semiconductor memory device may efficiently perform a refresh operation, and ensure reliability of stored data by preventing data loss.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device comprising:
a normal command generation unit suitable for generating a normal refresh command in response to a refresh command;
a smart command generation unit suitable for performing a counting operation on the normal refresh command to generate a plurality of smart refresh commands which are activated at a predetermined period; and
a refresh operation unit suitable for performing a refresh operation in response to the normal refresh command and the plurality of smart refresh commands,
wherein the smart command generation unit resets the counting operation when entering into the refresh operation.

2. The semiconductor memory device of claim 1, wherein the plurality of smart refresh commands are activated in a given sequence at each predetermined period.

3. The semiconductor memory device of claim 1, wherein the plurality of smart refresh commands include first and second smart refresh commands, and the first smart refresh command is activated prior to the second smart refresh command at each predetermined period.

4. The semiconductor memory device of claim 1, wherein the smart command generation unit comprises:
a command counting unit suitable for counting the refresh command and generating the plurality of smart refresh commands; and
a reset control unit suitable for resetting the command counting unit when entering into the refresh operation.

5. The semiconductor memory device of claim 1, wherein the refresh operation unit sequentially activates a plurality of word lines in response to the normal refresh command while activating word lines, which are adjacent to a frequently activated word line among the plurality of word lines, in a given sequence in response to the plurality of smart refresh commands.

6. A semiconductor memory device comprising:
a normal command generation unit suitable for generating a normal refresh command during a refresh operation;
a smart command generation unit suitable for generating a plurality of smart refresh commands during the refresh operation, and outputting the plurality of smart refresh commands in response to a preset priority; and
a refresh operation unit suitable for performing the refresh operation in response to the normal refresh command and the plurality of smart refresh commands.

7. The semiconductor memory device of claim 6, wherein the refresh operation unit comprises:
a memory bank including a plurality of word lines; and
an address control unit suitable for generating addresses corresponding to the plurality of word lines and driving the plurality of word lines in response to the normal refresh command and the plurality of smart refresh commands.

8. The semiconductor memory device of claim 7, wherein the address control unit sequentially drives the plurality of word lines in response to the normal refresh command while driving word lines, which are grouped based on word line activation frequency using the preset priority in response to the plurality of smart refresh commands.

9. The semiconductor memory device of claim 6, wherein the plurality of smart refresh commands are activated to correspond to at least one word line among the plurality of word lines.

10. The semiconductor memory device of claim 6, wherein the smart command generation unit is reset before generating the plurality of smart refresh commands.

11. The semiconductor memory device of claim 6, wherein the refresh operation unit sequentially activates a plurality of word lines in response to the normal refresh command while activating word lines, which are grouped based on group information among the plurality of word lines, in response to the plurality of smart refresh commands.

12. The semiconductor memory device of claim 6, wherein an activation period of the refresh command is set based on the priority and the priority is set based on the group information.

13. A refresh control system comprising:
a semiconductor memory device including a plurality of word lines which are grouped based on group information during a smart refresh operation; and
a memory controller suitable for changing a period of the refresh operation of the semiconductor memory device in response to the group information on the plurality of word lines,
wherein the semiconductor memory device performs the smart refresh operation based on the refresh operation.

14. The refresh control system of claim 13, wherein the plurality of word lines is activated in response to a priority information during the smart refresh operation.

15. The refresh control system of claim 14, wherein the memory controller comprises:
a priority decision unit suitable for generating the priority information for determining an activation sequence of the plurality of word lines in response to the group information; and
a refresh period setting unit suitable for setting the period of the refresh operation in response to the priority information.

16. The refresh control system of claim 15, wherein the semiconductor memory device performs the smart refresh operation in response to the refresh operation and the priority information.

17. The refresh control system of claim 13, wherein the semiconductor memory device performs a normal refresh operation on the plurality of word lines in response to the refresh operation.
